(19) United States
(12) Patent Application Publication
(10) Pub. No.: US 2010/0073020 A1
(43) Pub. Date: Mar. 25, 2010

(54) Probe of electrical measuring instrument

(75) Inventors: Jae Deok Lim, Suwon-si (KR); Byong Su Seol, Yongin-si (KR); Jong Sung Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,490

(22) Filed: Sep. 16, 2009

(30) Foreign Application Priority Data
Sep. 24, 2008 (KR) 10-2008-0093593

(51) Int. Cl. G01R 31/02

(52) U.S. Cl. 324/754

(57) ABSTRACT

Disclosed is a probe of an electrical measuring instrument including a handle and at least one loop antenna coupled to the handle. A plane defined by the loop antenna is oriented to face an object to be inspected, to detect electrical characteristics in the vicinity of the object. Enhanced accessibility of the probe with respect to the object to be inspected results in an improvement in the accuracy of measured electrical characteristics information and use convenience of the probe by an inspector.

### CROSS-REFERENCE TO RELATED APPLICATION(S)

This application claims priority under 35 U.S.C. §119 to Korean Patent Application No. 10-2008-0093593, filed on Sep. 24, 2008 in the Korean Intellectual Property Office (KIPO), the entire contents of which are herein incorporated by reference.

### BACKGROUND

1. Field

Example embodiments of the present invention relate to a measuring instrument, and, more particularly, to a probe of an electrical measuring instrument to detect electrical characteristics of an object to be inspected.

2. Description of the Related Art

Electrical characteristics of electric/electronic fields may be measured by a variety of measuring instruments, for example, a voltmeter, an ammeter, and/or an oscilloscope. Examples of electrical characteristics that may be measured by the aforementioned measuring instruments may include a voltage, a current, an electric field, and/or a magnetic field. Conventional measuring instruments may include a body and a probe electrically connected to the body. The measuring instrument may receive information of an object to be measured via the probe allowing a user to analyze the information. Therefore, the accuracy of the electrical characteristics information and the use convenience of the probe by an inspector are determined in accordance with the ability of the probe to access the object.

For example, detecting a current flowing through a patterned signal line on a printed circuit board may require that two probes be brought into electrical contact with two positions on the signal line. When it is desired to detect the magnitude of current flowing through the signal line via a detection of a magnetic field around the signal line, the ability of the probe to access an object is important for accurate detection. Accessibility of the probe is important for accurate detection because the detected magnitude of current may change according to a flux of the magnetic field and/or a relative position of the probe.

### SUMMARY

Example embodiments of present invention provide a probe for an electrical measuring instrument, which may have enhanced accessibility with respect to an object to be inspected, resulting in an improvement in the accuracy of measured electrical characteristics information and use convenience of the probe by an inspector.

Additional aspects and/or advantages of the invention will be set forth in part in the description which follows and, in part, will be obvious from the description, or may be learned by practice of the invention.

In accordance with an example embodiment of the present invention, a probe for inspecting an object may include a handle and at least one loop antenna coupled to the handle, wherein a plane defined by the at least one loop antenna is oriented to face the object to be inspected, to detect electrical characteristics in a vicinity of the object.

In accordance with another example embodiment of the present invention, a probe for inspecting an object may include a handle, and a pair of loop antennas coupled to the handle and arranged parallel to each other in a single plane, the pair of loop antennas defining a plane facing the object to be inspected to detect electrical characteristics in a vicinity of the object.

In accordance with another example embodiment of the present invention, a probe for inspecting an object may include a handle, a pair of loop antennas coupled to the handle, the pair of loop antennas being arranged parallel to each other in a plane, and a protective member enclosing and protecting the pair of loop antennas, wherein the plane faces the object to be inspected to detect electrical characteristics in a vicinity of the object.

In accordance with another example embodiment of the present invention, a probe for inspecting an object may include a handle and a pair of loop antennas arranged parallel to each other in a single plane to detect electrical characteristics in a vicinity of the object, wherein the pair of loop antennas are detachably coupled to the handle.

In accordance with another example embodiment of the present invention, In accordance with example embodiments, a probe for inspecting an object may include a handle, at least one loop antenna coupled to the handle, a protective member enclosing and protecting the at least one loop antenna, and a plurality of shields provided at the protective member to surround the at least one loop antenna to intercept noise.

In accordance with another example embodiment of the present invention, In accordance with example embodiments, a probe for inspecting an object may include a handle, at least one loop antenna coupled to the handle, and a chock electrically connected to the at least one loop antenna and used to intercept common mode noise.

In accordance with another example embodiment of the present invention, a method of inspecting an object may include positioning a probe near the object, the probe including a handle and at least one loop antenna coupled to the handle, wherein a plane defined by the at least one loop antenna is oriented to face the object to detect electrical characteristics in a vicinity of the object.

In accordance with another example embodiment of the present invention, a system for measuring an object may include a probe including a handle and at least one loop antenna coupled to the handle, wherein a plane defined by the at least one loop antenna is oriented to face the object to be inspected to detect electrical characteristics in a vicinity of the object. In accordance with example embodiments, the system for measuring an object may also include a measuring instrument electrically connected to the handle of the probe.

In accordance with another example embodiment of the present invention, a probe may include a handle and at least one loop antenna coupled to the handle, wherein a plane defined by the loop antenna may be oriented to face an object to be inspected, to detect electrical characteristics in the vicinity of the object.

The handle and loop antenna may be coupled to each other such that a longitudinal direction of the handle follows a normal direction of the plane of the loop antenna.

The handle and loop antenna may be coupled to each other such that the longitudinal direction of the handle is tilted by a preset angle from the normal direction.

The loop antenna may be electrically connected to a measuring instrument via the handle.

The electrical characteristics may include a magnetic field.

In accordance with another example embodiment the present invention, a probe may include a handle and a pair of loop antennas coupled to the handle. The pair of loop antennas may be parallel to each other to define a single plane. The plane of the pair of loop antennas may be oriented to face an object to be inspected, to detect electrical characteristics in the vicinity of the object.

The handle and the pair of loop antennas may be coupled to each other such that a longitudinal direction of the handle follows a normal direction of the plane of the pair of loop antennas.

The handle and the pair of loop antennas may be coupled to each other such that the longitudinal direction of the handle is tilted by a preset angle from the normal direction.

The pair of loop antennas may be electrically connected to a measuring instrument via the handle.

An intermediate position between the pair of loop antennas may be located at a position to be inspected, to detect a magnetic field.

The pair of loop antennas may have a diagonally symmetrical configuration.

The electrical characteristics may include a magnetic field.

In accordance with another example embodiment the present invention, a probe may include a handle and a pair of loop antennas coupled to the handle. The pair of loop antennas may be arranged parallel to each other to define a single plane. The probe may also include a protective member to enclose and protect the pair of loop antennas, wherein the plane of the pair of loop antennas may be oriented to face an object to be inspected, to detect electrical characteristics in the vicinity of the object.

The protective member may be made of a transparent material.

The protective member may be made of an opaque material.

A mark to represent an intermediate position between the pair of loop antennas may be provided at a surface of the protective member.

The mark may be aligned with an inspecting position of the object, to detect a magnetic field in the vicinity of the object.

The electrical characteristics may include a magnetic field.

In accordance with another example embodiment of the present invention, a probe may include a handle and a pair of loop antennas detachably coupled to the handle. The pair of loop antennas may be arranged parallel to each other to define a single plane, wherein the plane of the pair of loop antennas may be oriented to face an object to be inspected, to detect electrical characteristics in the vicinity of the object.

Any one of a plurality of loop antennas defining different sizes of planes may be selected and coupled to the handle, to detect a magnetic field in the vicinity of the object.

The probe may further include an electric element electrically connected to the loop antennas to determine frequency characteristics of the loop antennas.

The electric element may be at least one of a capacitor, a resistor, and an inductor.

Any one of the plurality of loop antennas having different characteristics values of the electric element may be selected and coupled to the handle so as to detect a magnetic field in the vicinity of the object to be inspected.

The electrical characteristics may include a magnetic field.

In accordance with another example embodiment of the present invention, a probe may include a handle, at least one loop antenna coupled to the handle, a protective member to enclose and protect the at least one loop antenna, and a plurality of shields provided at the protective member to surround the at least one loop antenna and used to intercept noise to be introduced into the at least one loop antenna. The plane defined by the loop antenna may be oriented to face an object to be inspected, to detect electrical characteristics in the vicinity of the object.

Each of the plurality of shields may have a loop shape.

In accordance with another example embodiment of the present invention, a probe may include a handle, at least one loop antenna coupled to the handle, and a chock electrically connected to the at least one loop antenna and used to intercept common mode noise to be introduced via the loop antenna. The plane defined by the loop antenna may be oriented to face an object to be inspected, to detect electrical characteristics in the vicinity of the object.

### BRIEF DESCRIPTION OF THE DRAWINGS

These and/or other aspects and advantages of the example embodiments of the present invention will become apparent and more readily appreciated from the following description of the example embodiments, taken in conjunction with the accompanying drawings of which:

FIG. 1 is a view showing probes according to example embodiments of the present invention;

FIG. 2 is a view showing a detection of a magnetic field using a probe shown in FIG. 1;

FIG. 3 is a partial section view of a printed circuit board taken along III-III′ in FIG. 2, showing a detection of a magnetic field using the probe shown in FIG. 2;

FIG. 4 is a view showing probes according to other example embodiments of the present invention;

FIG. 5 is a view showing a detection of a magnetic field using a probe shown in FIG. 4;

FIG. 6 is a partial section view of a printed circuit board taken along VI-VI′ in FIG. 5, showing a detection of a magnetic field using the probe shown in FIG. 5;

FIG. 7 is a view showing a probe according to another example embodiment of the present invention;

FIG. 8 is a view showing a probe according to another example embodiment of the present invention;

FIG. 9 is a view showing a probe according to another example embodiment of the present invention;

FIG. 10 is a view showing a probe according to another example embodiments of the present invention;

FIG. 11 is a view showing a probe according to another example embodiments of the present invention;

FIG. 12 is a view showing a probe according to another example embodiment of the present invention; and

FIG. 13 is a view showing a probe according to another example embodiment of the present invention.

### DETAILED DESCRIPTION

Example embodiments of the present invention will now be described more fully with reference to the accompanying drawings, in which example embodiments of the present invention are shown. The invention may, however, be embodied in different forms and should not be construed as limited to the example embodiments set forth herein. Rather, these example embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of the example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Example embodiments of the present invention described herein will refer to plan views and/or cross-sectional views by way of ideal schematic views. Accordingly, the views may be modified depending on manufacturing technologies and/or tolerances. Therefore, example embodiments of the present invention are not limited to those shown in the views, but include modifications in configuration formed on the basis of manufacturing processes. Therefore, regions exemplified in figures have schematic properties and shapes of regions shown in figures exemplify specific shapes or regions of elements, and do not limit the example embodiments of the present invention.

Reference will now be made in detail to the example embodiments of the present invention, examples of which are illustrated in the accompanying drawings, wherein like reference numerals refer to the like elements throughout.

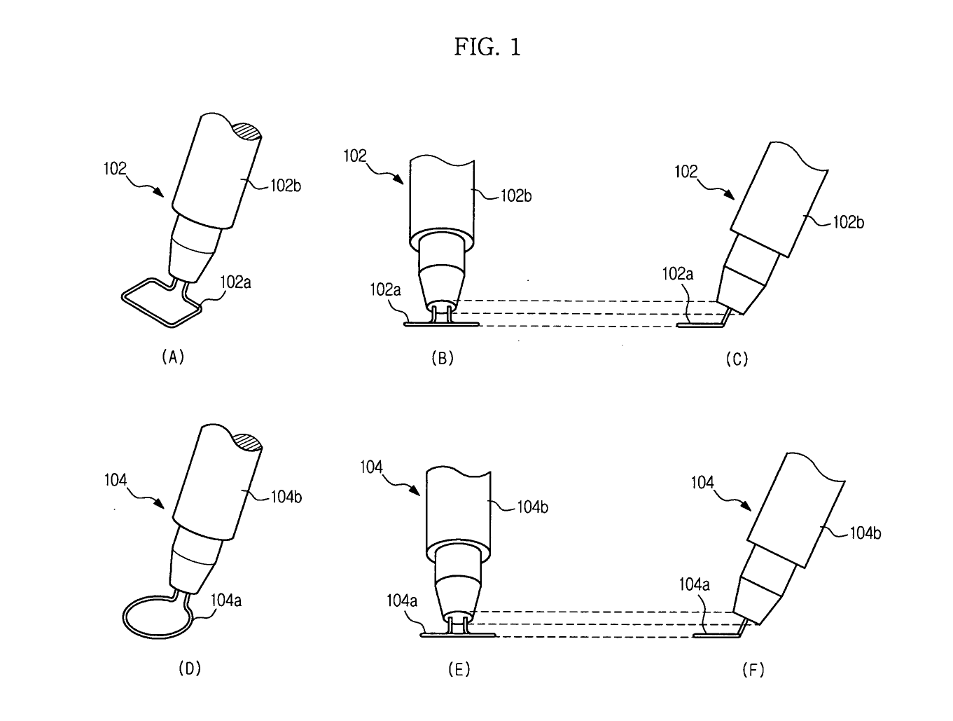

Hereinafter, example embodiments of the present invention will be described with reference to FIGS. 1 to 13.

FIG. 1 is a view showing probes according to example embodiments of the present invention. More particularly, FIG. 1A shows a probe 102, wherein a rectangular loop antenna 102a may be coupled to a handle 102b. FIG. 1B is a front view of the probe 102, and FIG. 1C is a side view of the probe 102. The handle 102b of the probe 102 may have a pen shape, allowing an inspector to grip the probe 102 as one would hold a pen. The handle 102b may be coupled to the loop antenna 102a in such a manner that a longitudinal direction of the handle 102b may follow an approximately normal direction of a rectangular plane defined by the loop antenna 102a. More specifically, the handle 102b may be coupled to the loop antenna 102a by a slight tilt angle from the normal direction of the rectangular plane of the loop antenna 102a. With this coupling manner, when the inspector moves the probe 102 to a position to be inspected, the inspector may accurately locate the loop antenna 102a at the inspecting position while confirming the inspecting position as well as a position of the loop antenna 102a. Further, gripping the probe 102 like a pen may cause the plane of the loop antenna 102a to face downward, thereby allowing the entire loop antenna 102a to be brought near a surface of an object to be inspected (for example, a Printed Circuit Board (PCB)). That is, the inspector may be able to detect a magnetic field after moving the loop antenna 102a to an inspection position by gripping the probe 102 as one would hold a pen.

In another example embodiment of the present invention, the longitudinal direction of the handle 102b may be completely perpendicular to the plane of the loop antenna 102a. In another example embodiment of the present invention, the loop antenna 102a and handle 102b may be in a straight line. Specifically, the shape of the handle and the coupling manner between the handle and the loop antenna may be determined to allow the plane of the loop antenna to be parallel to a surface of an object to be inspected.

In addition, FIG. 1D shows a probe 104 wherein a circular loop antenna 104a may be coupled to a handle 104b. FIG. 1E is a front view of the probe 104, and FIG. 1F is a side view of the probe 104. Similar to the previously described probe 102, the inspector grips the probe 104 as one would hold a pen.

In all the example embodiments of the present invention disclosed herein, a metal constituting the loop antenna of the probe may be made as thin as possible. In the example embodiments of the present invention, measurement of current is based on detection of a magnetic field (commonly denoted by H) and therefore, the effect of an electric field (commonly denoted by E) may be minimized for accurate measurement of the magnetic field. For this, the metal of the loop antenna may be made as thin as possible.

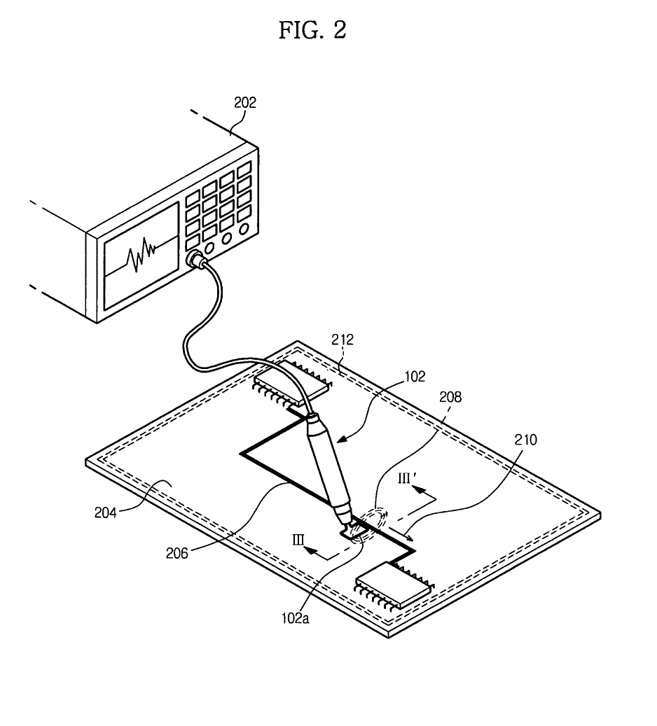

FIG. 2 is a view showing a detection of a magnetic field using the probe 102 shown in FIG. 1. As shown in FIG. 2, one-end of the handle 102b of the probe 102 may be electrically connected to a measuring instrument 202. In FIG. 2, when current for transmission of electrical signals flows through a patterned signal line 206 printed on a printed circuit board 204, a magnetic field 208 is created around the signal line 206 by the current flow. If the loop antenna 102a is located in the magnetic field 208, an electromotive force may be generated in the loop antenna 102a. The measuring instrument 202 may detect and display the magnitude of current flowing through the signal line 206 based on the magnitude of the electromotive force. In FIG. 2, an arrow 210 represents the direction of current flowing through the signal line 206. Also, the magnetic field 208 has a magnetic line direction as shown in FIG. 2.

The printed circuit board 204 may require a ground line 212 as well as a power line. The ground line 212 may be provided at one surface of the printed circuit board 204 opposite to the other surface at which the signal line 206 is provided. If current flows through the signal line 206, the current may also flow through the ground line 212. Accordingly, a slight magnetic field may be created throughout the printed circuit board 204 owing to the current flowing through the ground line 212. If the loop antenna for detection of a magnetic field is oriented perpendicular to the printed circuit board 204, rather than being horizontal thereto, the loop antenna may detect a magnetic field created from the ground line 212 as well as the magnetic field 208 created from the signal line 206, resulting in deterioration in the detection accuracy of a magnetic field. However, in the example embodiments of the present invention disclosed herein, the loop antenna may be oriented horizontal (parallel) to the printed circuit board 204 upon detection of a magnetic field, and may not be affected by the magnetic field created from the ground line 212. Accordingly, the example probes may achieve an improvement in the detection accuracy of a magnetic field.

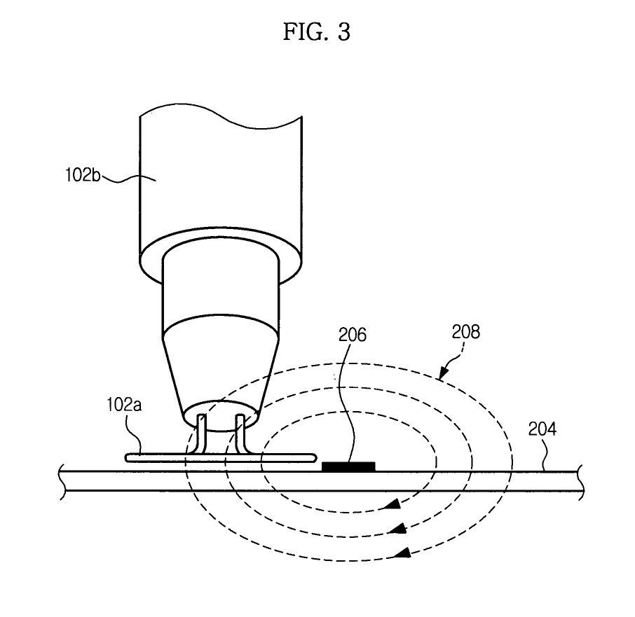

FIG. 3 is a partial section view of the printed circuit board 204 taken along III-III′ in FIG. 2, showing detection of a magnetic field using the probe 102. When magnetic lines of the magnetic field 208 created by the current flowing through the signal line 206 are perpendicular to the plane of the loop antenna 102a, the largest electromotive force is generated. Accordingly, as shown in FIG. 3, upon detection of a magnetic field (current), the inspector may place the loop antenna 102a close to the surface of the printed circuit board 204 immediately near the signal line 206 such that magnetic lines of the magnetic field 208 are perpendicular to the plane of the loop antenna 102a.

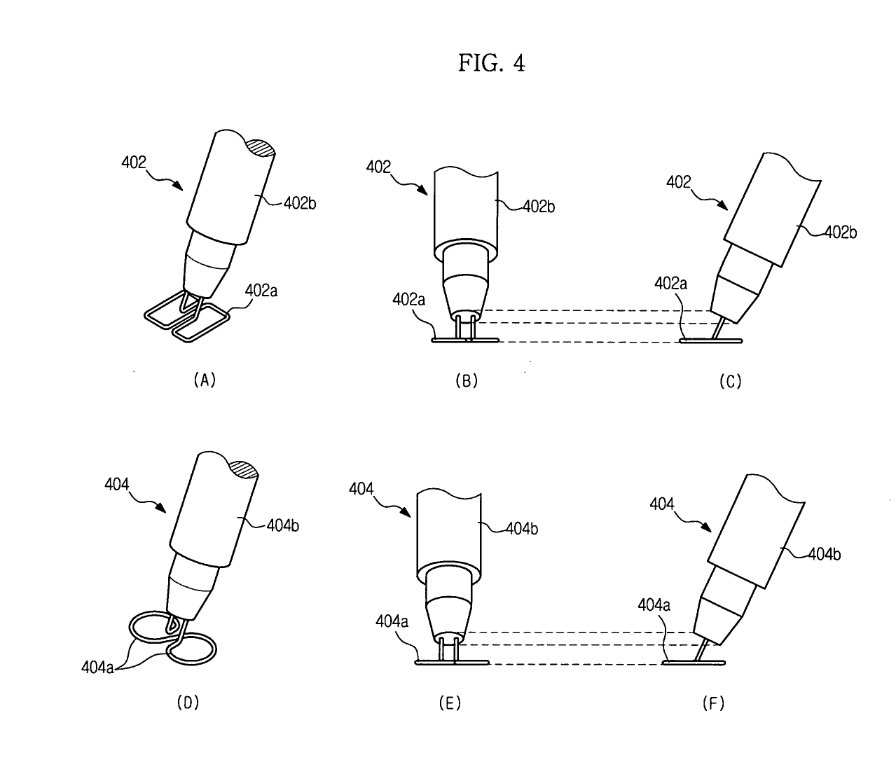

FIG. 4 is a view showing probes according to other example embodiments of the present invention. More particularly, FIG. 4A shows a probe 402 wherein a pair of rectangular loop antennas 402a, which may be arranged in parallel to define a single plane, may be coupled to a handle 402b. FIG. 4B is a front view of the probe 402, and FIG. 4C is a side view of the probe 402. The handle 402b of the probe 402 may have a pen shape, allowing an inspector to grip the probe 402 as one would hold a pen. The handle 402b may be coupled to the pair of loop antennas 402a in such a manner that a longitudinal direction of the handle 402b may follow an approximately normal direction of the rectangular planes of the loop antennas 402a. More specifically, the handle 402b may be coupled to the loop antennas 402a by a slight tilt angle from the normal direction of the planes of the loop antennas 402a. With this coupling manner, when the inspector moves the probe 402 to a position to be inspected, the inspector can accurately locate the loop antennas 402a at the inspecting position by easily confirming the inspecting position as well as positions of the loop antennas 402a. Further, gripping the probe 402 like a pen may cause the planes of the loop antennas 402a to face downward, thereby allowing the loop antennas 402a to easily be brought into contact with an object to be detected (for example, a Printed Circuit Board (PCB)). The inspector may be able to detect a magnetic field after locating the loop antennas 402a at a position to be inspected by gripping the probe 402 as one would hold a pen. Alternatively, the longitudinal direction of the handle 402b may be perpendicular to the planes of the loop antennas 402a.

In addition, FIG. 4D shows a probe 404 wherein a pair of circular loop antennas 404a may be coupled to a handle 404b. FIG. 4E is a front view of the probe 404, and FIG. 4F is a side view of the probe 404. Similar to the previously described probe 402, the inspector grips the probe 404 as one would hold a pen.

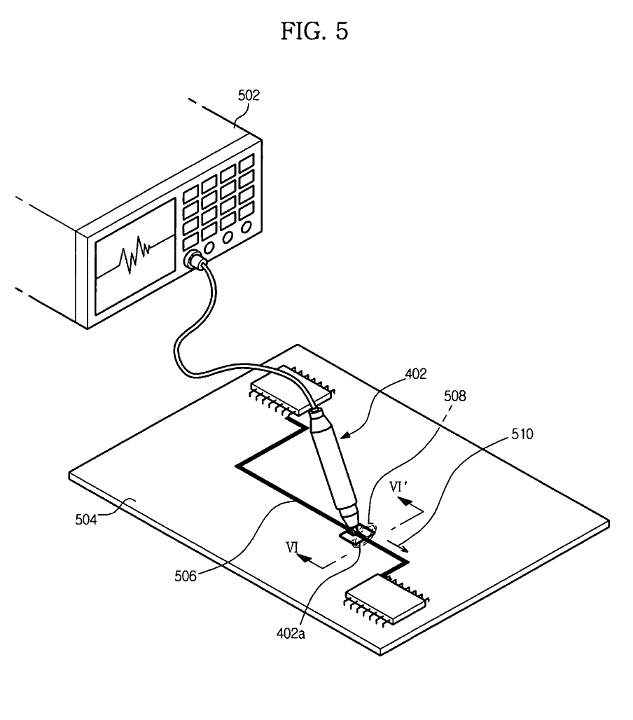

FIG. 5 is a view showing a detection of a magnetic field using the probe 402 shown in FIG. 4. As shown in FIG. 5, one end of the handle 402b of the probe 402 may be electrically connected to a measuring instrument 502. In FIG. 5, when current for transmission of electrical signals flows through a patterned signal line 506 printed on a printed circuit board 504, a magnetic field 508 is created around the signal line 506 by the current flow. If the loop antennas 402a are located in the magnetic field 508, an electromotive force is generated in the loop antennas 402a. The measuring instrument 502 may detect and display the magnitude of current flowing through the signal line 506 based on the magnitude of the electromotive force. That is, the probe 402 of the present embodiment may detect a magnetic field around the signal line 506, and may detect current flowing through the signal line 506 based on the magnetic field. In FIG. 5, an arrow 510 represents the direction of current flowing through the signal line 506. Also, the magnetic field 508 has a magnetic line direction as shown in FIG. 5.

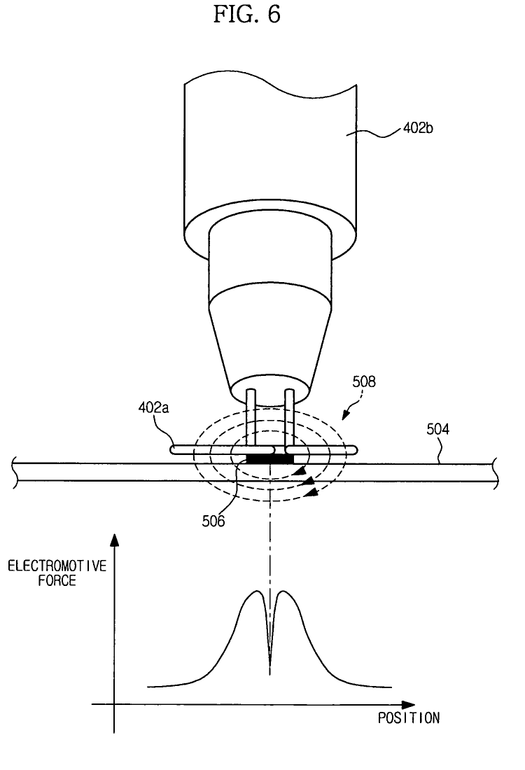

FIG. 6 is a partial section view of the printed circuit board 504 taken along VI-VI′ in FIG. 5, showing a detection of a magnetic field using the probe 402. When magnetic lines of the magnetic field 508 created by the current flowing through the signal line 506 are perpendicular to the planes of the loop antennas 402a, the largest electromotive force is generated. Accordingly, as shown in FIG. 6, upon detection of a magnetic field (current), the inspector may place the loop antennas 402a close to a surface of the signal line 506 immediately above the signal line 506 such that magnetic lines of the magnetic field 508 around the signal line 506 are perpendicular to the respective planes of the pair of loop antennas 402a.

The probe 402 having the pair of loop antennas 402a may detect a magnetic field created at both sides of the signal line 506. Representing the magnitude of electromotive force generated by the magnetic field around the signal line 506, as shown in the lower part of FIG. 6, it can be appreciated that the electromotive force becomes the largest at both sides of the signal line 506. Accordingly, if an intermediate position of the pair of loop antennas 402a is located immediately above the signal line 506, the respective loop antennas 402a are naturally located at both sides of the signal line 506, thereby enabling detection of the largest magnetic field around the signal line 506, resulting in a significant improvement in the detection accuracy of a magnetic field.

In addition, as shown in FIG. 6, the loop antennas 402a may have opposite flux directions to each other. Specifically, a magnetic flux passes upward from the printed circuit board 504 through any one of the pair of loop antennas 402a, and passes downward toward the printed circuit board 504 through the other loop antenna 402a. Therefore, as shown in FIG. 4, the loop antennas 402a may be spiraled in opposite directions, (i.e. are symmetrical in opposite diagonal directions), thereby detecting all magnetic fluxes generated toward opposite directions from each other at both sides of the signal line 506. This configuration is similar to the pair of circular loop antennas 404a shown in FIG. 4D.

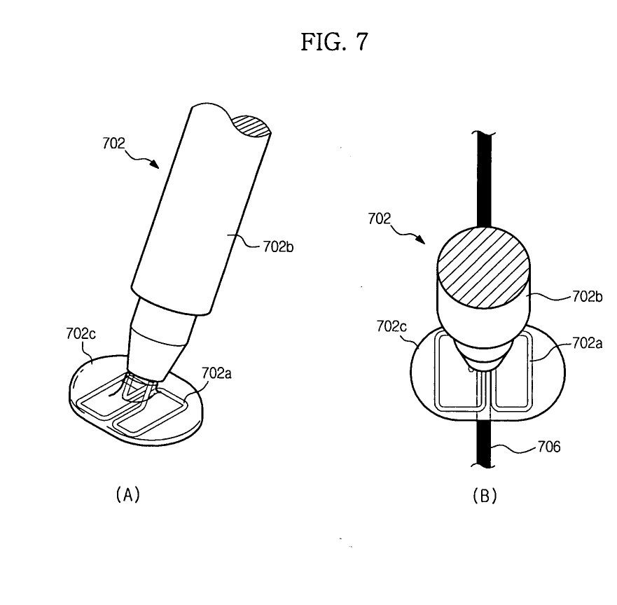

FIG. 7 is a view showing a probe according to another example embodiment of the present invention. As shown in FIG. 7, a pair of loop antennas 702a may be coupled to a handle 702b of a probe 702 and the pair of loop antennas 702a may be enclosed and protected by a protective member 702c. The protective member 702c, may, for example, be made of a transparent synthetic resin. Because the loop antennas 702a may have a relatively thin thickness, the loop antennas 702a may be easily damaged by external shock or may be contaminated by contaminants. Therefore, the protective member 702c may be provided to enclose the loop antennas 702a thereby protecting the loop antennas 702a from external shock and contamination.

To assure accurate detection of a magnetic field, a signal line 706 may be located midway between the pair of loop antennas 702a (see the above description of FIG. 6). For this, using the transparent protective member 702c to visually confirm the signal line 706 and loop antennas 702a allows the inspector to adjust a position of the loop antennas 702a to align an intermediate position between the pair of loop antennas 702a with the signal line 706.

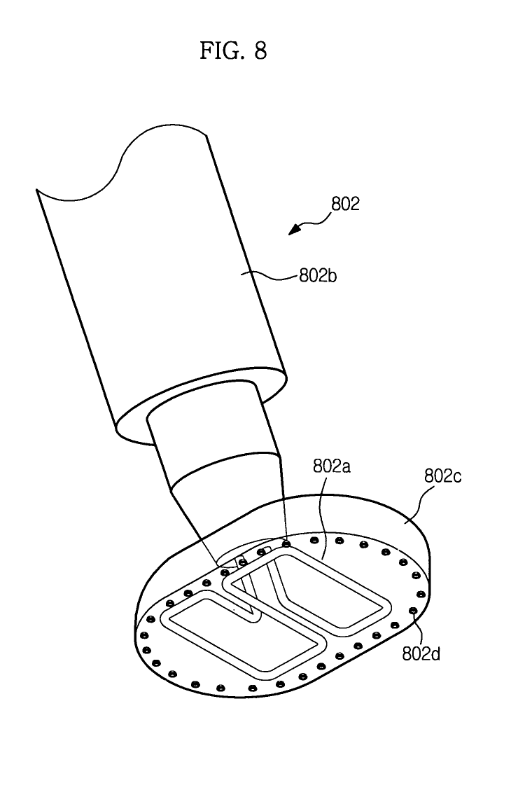

FIG. 8 is a view showing a probe according to another example embodiment of the present invention. As shown in FIG. 8, a pair of loop antennas 802a may be coupled to a handle 802b of a probe 802 and the pair of loop antennas 802a may be enclosed and protected by a protective member 802c, which may be made of, for example, transparent synthetic resin. A plurality of loop-shaped shields 802d may be arranged at a lower surface of the protective member 802c around the loop antennas 802a, to intercept noise generated by unwanted magnetic fields. In the case of a complicated arrangement of a plurality of signal lines, there is a risk in that detecting a magnetic field of a target position around one signal line is hindered by a magnetic field around a neighboring signal line. The shields 802c may minimize or eliminate the effect of an unwanted magnetic field.

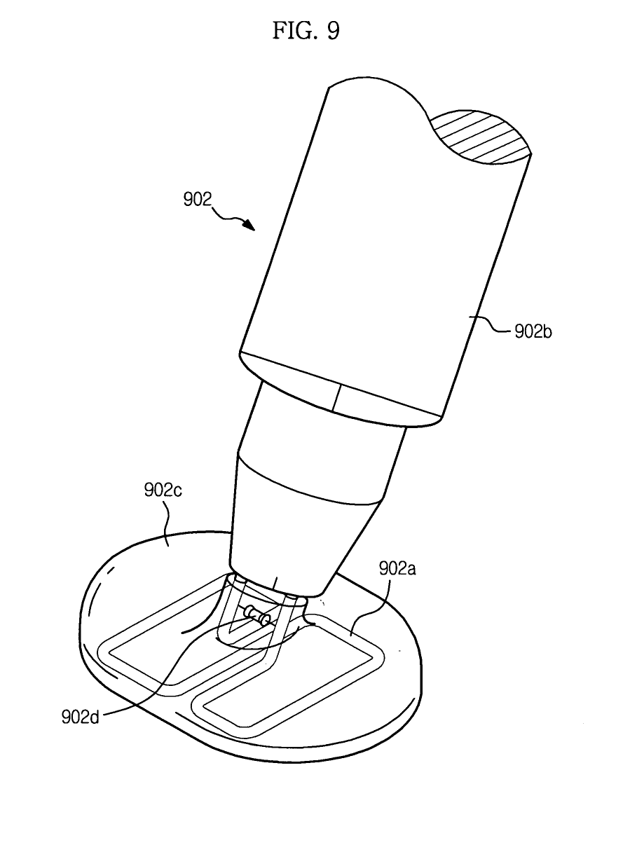

FIG. 9 is a view showing a probe according to another example embodiment of the present invention. As shown in FIG. 9, a pair of loop antennas 902a may be coupled to a handle 902b of a probe 902 and the pair of loop antennas 902a may be enclosed and protected by a protective member 902c, which may be made of, for example, synthetic resin. A resistor 902d may be installed between opposite distal ends of the loop antennas 902a as coupling ends with the handle 902b. The resistor 902d may cause constant frequency characteristics, for example, a constant flat s-parameter of the loop antennas 902a, thereby improving the detection accuracy of a magnetic field of the loop antennas 902a. Example embodiments of the present invention are not limited to the use of a resistor to change electrical characteristics of the probe, for example, the resistor 902d may be replaced with at least one of a capacitor and an inductor.

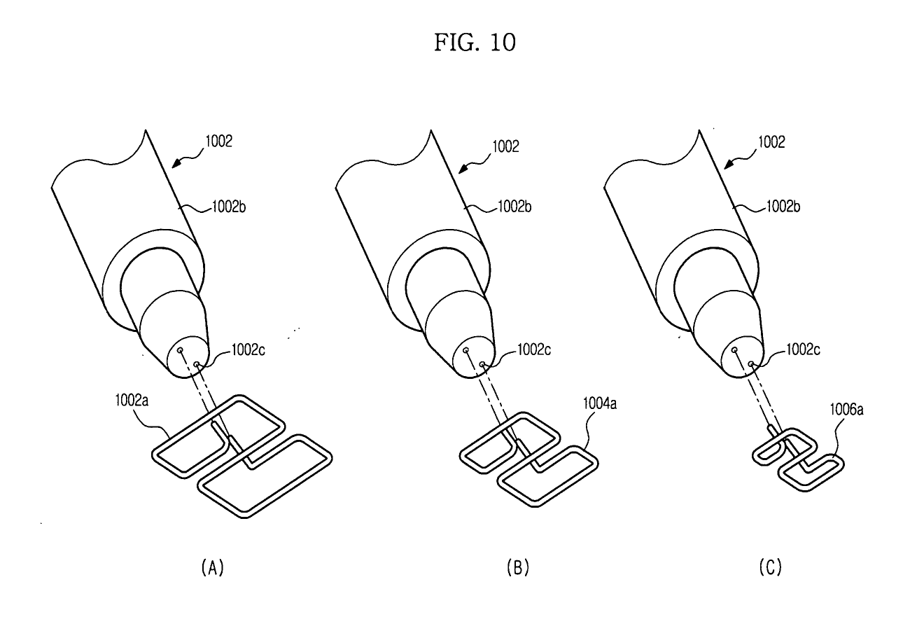

FIG. 10 is a view showing a probe according to another example embodiment of the present invention. As shown in FIG. 10, a handle 1002b may be formed with coupling holes 1002c and any one of various sizes of loop antennas 1002a, 1004a and 1006a may be selectively coupled to the handle 1002b via the coupling holes 1002c. If an inspector selects a desired size of loop antennas 1002a, 1004a or 1006a as necessary, the selected loop antennas may be coupled to the handle 1002b via the coupling holes 1002c, completing the probe 1002. Generally, signal lines printed on a printed circuit board may contain various widths and intervals. If large size loop antennas 1002a are used with a printed circuit board having a narrow width of signal lines and a narrow interval between neighboring signal lines, there is a risk of detecting a magnetic field around an undesignated signal line. Accordingly, when signal lines have a narrow width and narrow interval therebetween, a small size of loop antennas 1006a may be selected to enable more accurate detection of a magnetic field. Although not shown in FIG. 10, the loop antennas 1002a, 1004a or 1006a may be enclosed and protected by the protective member 702c as shown in FIG. 7.

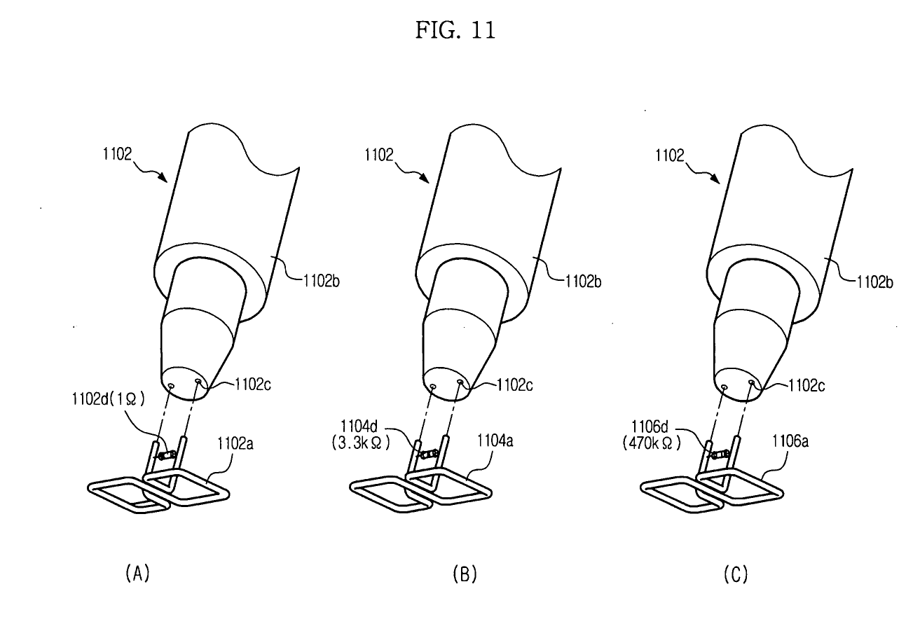

FIG. 11 is a view showing a probe according to another example embodiment of the present invention. As shown in FIG. 11, a handle 1102b may be formed with coupling holes 1102c. Various kinds of loop antennas 1102a, 1104a and 1106a, having different resistance values, may be provided and selectively coupled to the handle 1102b via the coupling holes 1102c. If the inspector selects a desired resistance value of loop antennas 1102a, 1104a or 1106a as necessary, the selected loop antennas may be coupled to the handle 1102b via the coupling holes 1102c, completing the probe 1102. The loop antennas 1102a, 1104a or 1106a may have a resistor 1102d, 1104d or 1106d that may have a resistance value suitable for a desired s-parameter. Accordingly, selective use of the loop antennas 1102a, 1104a or 1106a may enable more accurate detection of a magnetic field. Although not shown in FIG. 11, the loop antennas 1102a, 1104a or 1106a may be enclosed and protected by the protective member 702c as shown in FIG. 7.

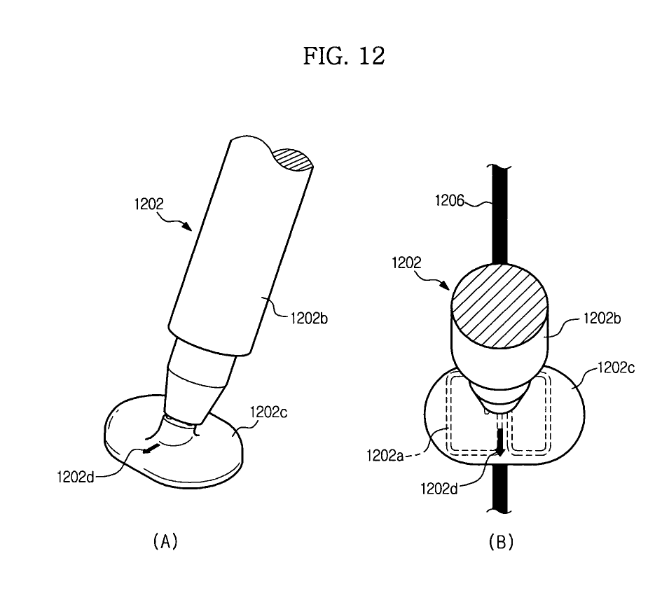

FIG. 12 is a view showing a probe according to another example embodiment of the present invention. As shown in FIG. 12, a pair of loop antennas 1202a coupled to a handle 1202b of a probe 1202 may be enclosed and protected by a protective member 1202c, which is made of, for example, opaque synthetic resin. The loop antennas 1202a may have a relatively thin thickness and may be easily damaged by external shock or may be contaminated by contaminants. Therefore, the protective member 1202c may enclose and protect the loop antennas 1202a from external shock and contamination.

To assure accurate detection of a magnetic field, a signal line 1206 may be located midway between the pair of loop antennas 1202a (see the above description of FIG. 6). For this, a mark 1202d representing an intermediate position between the pair of loop antennas 1202a may be provided at a surface of the opaque protective member 1202c. Upon detection of a magnetic field using the probe 1202, the inspector may locate the probe 1202 above the signal line 1206 such that the mark 1202d is aligned with the signal line 1206, enabling accurate detection of a magnetic field.

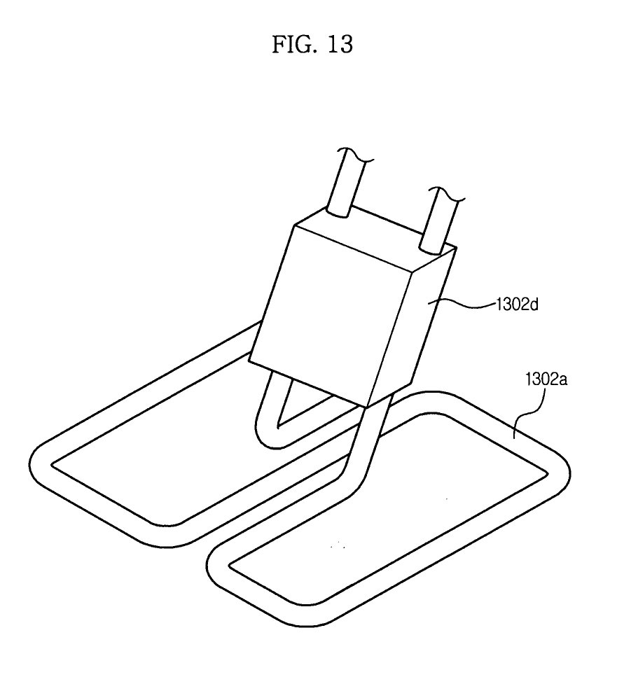

FIG. 13 is a view showing a probe according to another example embodiment of the present invention. As shown in FIG. 13, a common mode chock 1302d may be installed at upper ends of a pair of loop antennas 1302a. The common mode chock 1302d may intercept common mode noise to be introduced via the loop antennas 902a, improving detection accuracy of a magnetic field of the loop antennas 1302a. By adjusting electrical characteristics of the common mode chock 1302d (for example, the number of coil turns, etc.), selective interception of low-frequency noise or high-frequency noise may be possible.

Although a few example embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A probe for inspecting an object, the probe comprising:
a handle; and
at least one loop antenna coupled to the handle,
wherein a plane defined by the at least one loop antenna is oriented to face the object to be inspected to detect electrical characteristics in a vicinity of the object.

2. The probe according to claim 1, wherein a longitudinal direction of the handle is substantially normal to the plane defined by the at least one loop antenna.

3. The probe according to claim 1, wherein a longitudinal direction of the handle is tilted by a preset angle from a direction normal to the plane defined by the at least one loop antenna.

4. The probe according to claim 1, wherein the at least one loop antenna is configured to electrically connect to a measuring instrument via the handle.

5. The probe according to claim 1, wherein the electrical characteristics include a magnetic field.

6. A probe for inspecting an object, the probe comprising:
a handle; and
a pair of loop antennas coupled to the handle and arranged parallel to each other in a single plane, the pair of loop antennas defining a plane facing the object to be inspected to detect electrical characteristics in a vicinity of the object.

7. The probe according to claim 6, wherein a longitudinal direction of the handle is substantially normal to the plane defined by the pair of loop antennas.

8. The probe according to claim 6, wherein a longitudinal direction of the handle is tilted by a preset angle from a direction normal to the plane defined by the pair of loop antennas.

9. The probe according to claim 6, wherein the pair of loop antennas is configured to electrically connect to a measuring instrument via the handle.

10. The probe according to claim 6, wherein the pair of loop antennas include an intermediate position for positioning the pair of loop antennas at a position to detect a magnetic field

11. The probe according to claim 6, wherein the pair of loop antennas is diagonally symmetric.

12. The probe according to claim 6, wherein the electrical characteristics include a magnetic field.

13. A probe for inspecting an object, the probe comprising:
a handle;
a pair of loop antennas coupled to the handle, the pair of loop antennas being arranged parallel to each other in a plane; and
a protective member enclosing and protecting the pair of loop antennas;
wherein the plane faces the object to be inspected to detect electrical characteristics in a vicinity of the object.

14. The probe according to claim 13, wherein the protective member includes a transparent material.

15. The probe according to claim 13, wherein the protective member includes an opaque material.

16. The probe according to claim 15, wherein the protective member includes a mark to represent an intermediate position between the pair of loop antennas.

17. The probe according to claim 16, wherein the mark is configured to align with an inspecting position of the object to detect a magnetic field in the vicinity of the object.

18. The probe according to claim 13, wherein the electrical characteristics include a magnetic field.

19. A probe for inspecting an object, the probe comprising:
a handle; and
a pair of loop antennas arranged parallel to each other in a single plane to detect electrical characteristics in a vicinity of the object, wherein the pair of loop antennas are detachably coupled to the handle.

20. The probe according to claim 19, wherein the handle is configured to attach to any one of a plurality of loop antennas defining different sizes of planes for detecting a magnetic field in the vicinity of the object.

21. The probe according to claim 19, further comprising:
an electric element electrically connected to the pair of loop antennas to determine frequency characteristics of the pair of loop antennas.

22. The probe according to claim 21, wherein the electric element is at least one of a capacitor, a resistor, and an inductor.

23. The probe according to claim 19, wherein the handle is configured to connect to any one of a plurality of loop antennas having different characteristics values of an electric element to detect a magnetic field in the vicinity of the object.

24. The probe according to claim 19, wherein the electrical characteristics include a magnetic field.

25. A probe for inspecting an object, the probe comprising:
a handle;
at least one loop antenna coupled to the handle;
a protective member enclosing and protecting the at least one loop antenna; and
a plurality of shields provided at the protective member to surround the at least one loop antenna to intercept noise.

26. The probe according to claim 25, wherein each of the plurality of shields has a loop shape.

27. A probe for inspecting an object, the probe comprising:
a handle;
at least one loop antenna coupled to the handle; and
a chock electrically connected to the at least one loop antenna and used to intercept common mode noise.
